(19) United States
(12) Patent Application Publication
(10) Pub. No.: US 2017/0354067 A1
(43) Pub. Date: Dec. 7, 2017

(54) POWER SYSTEM AND METHOD

(71) Applicant: AECOM AUSTRALIA PTY LTD, Fortitude Valley (AU)

(72) Inventor: Murray Dickinson, Panmure, Auckland (NZ)

(21) Appl. No.: 15/535,166

(22) PCT Filed: Dec. 10, 2015
(86) PCT No.: PCT/AU2015/050782

§ 371 Date: Jun. 12, 2017

(30) Foreign Application Priority Data
Dec. 15, 2014 (AU) 2014905066

(51) Int. Cl. H05K 7/20; H02J 9/06; H02J 3/46; G06F 1/32; H02J 3/14; H02J 1/12; H02M 5/40; H02J 7/00

(52) U.S. Cl. CPC H05K 7/20836; H02M 5/40; H02J 9/06; H02J 7/00; G06F 1/3287; H02J 3/14; H02J 1/12; H02J 3/46

(57) ABSTRACT

A power system (1), typically for use in a data centre, which eliminates use of a changeover device when switching between power sources. The power system (1) includes first and second rectifiers (5, 6), each of which is connected to a respective AC power source (2, 3), and an energy storage device (1).

### BACKGROUND OF THE INVENTION

The present invention relates to a power system and a method of implementing a power system. In particular, the present invention relates to the implementation of a power system for a data centre, wherein a changeover device, which is typically used in such a data centre in conjunction with various power sources, is substantially eliminated.

### DESCRIPTION OF THE PRIOR ART

The reference in this specification to any prior publication (or information derived from it), or to any matter which is known, is not, and should not be taken as, an acknowledgement or admission or any form of suggestion that prior publication (or information derived from it) or known matter forms part of the common general knowledge in the field of endeavour to which this specification relates.

Data centres typically house large numbers of computer servers, storage devices, and communications devices. Most data centres are continuously powered and fully operational 24 hours per day every day of the year. If the power supply to the data centre switches off then the computer systems connected to the power supply will also switch off causing loss of service and loss of revenues.

A data centre is typically powered by electricity sourced from the local electricity grid. Alternate back up power is typically provided from standby diesel generators provided to make the data centre less sensitive to a grid power failure. The standby generators automatically start and take over supplying power to the site upon failure of the grid electricity supply. A changeover switching mechanism is normally provided to switch the data centre power source between grid power and standby generator power.

The start-up procedure can take several seconds before the standby systems are capable of providing power to the computer equipment. The data centre utilises some form of energy storage such as lead acid batteries or flywheels to provide enough energy to maintain full electrical power to the data centre computer systems during the period of time between a grid power failure event and the starting of the standby generators.

This energy storage device is maintained in a charged state by electronic devices called rectifiers. These convert the Grid alternating current (AC) power or the standby generator AC power to direct current (DC) to charge the batteries or flywheel.

Inverters are used to convert the stored DC energy into normal AC mains power for the data centre computer equipment.

When the Grid or Generators are active then the inverters receive energy from these sources. Whenever the Grid or Generators are not active then the inverters draw energy from the energy storage device. Thereby the data centre is provided with a no break power system.

Most suppliers call these systems “Uninterruptable Power Systems” or UPS.

The standby generators are regularly tested typically each month by simulating a grid power failure and allowing the generators to automatically start and transfer to support the load

This “no break” power system has a single point of failure in the form of the source changeover device that switches between grid power and standby generator power. Maloperation of this source changeover device often results in failure of the power supply to the computer equipment. This risk occurs whenever the power system is transferred between grid power and generator power such as when the grid fails or more frequently each time the standby generators are tested. As a result standby generator tests are carefully monitored and planned to coincide with periods of lower computer system loads

To improve reliability often a second duplicate no break power supply system is installed and the computer equipment provided with dual input power supplies each powered from a different no break power source.

Addition of a second duplicate source is costly and results in capital plant utilisation of less than 50%.

The no break power system design has evolved from computer room technology and usually consists of large rectifier and inverter modules operated either as standalone devices or in groups of several modules where one can be set aside as a redundant unit to provide additional resilience.

In the telecommunications industry the critical equipment has generally been designed to operate on 48 volt DC. This removes the need for Inverters as the equipment can be connected directly to the DC energy storage to provide a no break power supply. The removal of the inverter section of the no break power system improves the system resilience as there are fewer active devices in series.

Telecommunications facilities still typically use standby generators with source change over switches to provide secure power during loss of grid power.

The telecommunications industry rectifiers are a different topology to the standard data centre UPS rectifiers. Telecommunications rectifiers utilise a multiple micro-modular approach where smaller devices are installed in parallel with multiple spare devices. These are low cost modules that are hot swappable with multiple spare modules installed and active in each system. This parallel architecture dramatically improves resilience and when combined with the ability to easily replace failed units without disruption to the rectifier system results in a very high availability.

### SUMMARY OF THE INVENTION

The present invention seeks to overcome at least some of the disadvantages of the prior art.

The present invention seeks to provide a power system which is particularly suitable for but not limited for use with or in a data centre.

The present invention also seeks to provide a power system which substantially eliminates or at least minimises shut down time in the event of a power failure.

The present invention also seeks to eliminate the prior art requirement of including a changeover device in a data centre power system.

In one broad form, the present invention provides a power system, including:

a first rectifier, having an input adapted to be connected to a first AC (grid) power source, and, a DC output;

a second rectifier, having an input adapted to be connected to a second AC (backup generator) power source, and, a DC output, wherein the DC output of the first rectifier is directly connected to the DC output of the second rectifier;

an energy storage device battery, flywheel, super capacitors having an input connected to the DC outputs of each of the first and second rectifiers, and, a DC output; and

an inverter, having an input which is (directly) connected to the DC outputs of both the rectifiers and the energy storage device, and, an AC output which is adapted to be connected to an AC (data centre) load;

wherein, in use, the load is adapted to concurrently draw power from each inverter and\or the energy storage device.

Preferably, the power system further includes at least one additional rectifier, having, an input adapted to be connected to an additional AC power source, and, a DC output, wherein, the at least one additional rectifier is directly connected to the DC output of the first and second rectifiers.

Also preferably, each rectifier is connected to an AC power source including any one or combination of: a grid power source, a backup generator, a renewable energy source (including a wind or solar power source), or, any other power source.

Preferably, the energy storage device (battery) is adapted to directly supply DC power to a DC (data centre components) load, and may include any one of combinations of a battery, a flywheel, a super capacitor or any other energy storage device.

Also preferably, the DC outputs deliver a DC voltage which matches the DC input voltage of the (data centre)load components, such as, but not limited to 220V or 380V DC.

Preferably, each rectifier is embodied in a modular form (to facilitate quick and easy replacement).

Also preferably, each rectifier is a micro modular hot swappable rectifier.

Preferably the inverter is embodied in modular form (to facilitate quick and easy replacement).

Also preferably, said inverter is a micro modular hot swappable inverter.

In a further broad form, the present invention provides the power system as hereinbefore described, connected in parallel with one or more additional power system, to form a composite power distribution system (with additional redundancy).

In a further broad form, the present invention provides a modular form (micro modular hot swappable) rectifier, adapted to be used in the power system as hereinbefore described.

In yet a further broad form, the present invention provides a modular form (micro modular hot swappable) inverter, adapted to be used in the power system.

### BRIEF DESCRIPTION OF THE DRAWINGS

The present invention will become more fully understood from the following detailed description of preferred but non limiting embodiments thereof, described in connection with the accompanying drawing, wherein:

FIG. 1 illustrates a block diagram view of a preferred embodiment of the power system in accordance with an exemplary implementation of the present invention; and,

FIG. 2 illustrates a block diagram of a plurality of power systems of FIG. 1, connected in parallel with each other, to form a power distribution system in accordance with another preferred embodiment of the present invention.

### DETAILED DESCRIPTION OF THE INVENTION

Throughout the specification, like numerals will be used to identify like features, except where expressly otherwise indicated.

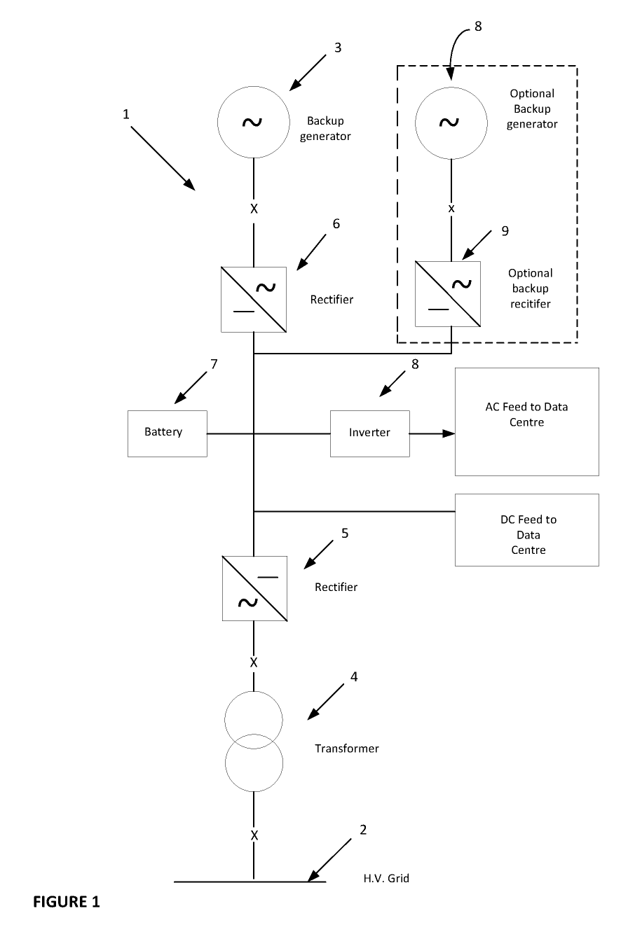

FIG. 1 shows a preferred but non-limiting exemplary embodiment of a power system in accordance with the present invention.

The power system, generally designated by reference numeral 1, is shown to be connected to an AC grid power supply 2, and also an AC backup generator 3. That is, the power system of the present invention is, in use, connected to at least two AC power sources.

The power system 1 includes a transformer 4 and a rectifier 5, to convert the AC grid supply 2 to a 220V DC output, and, another rectifier 6, to also convert the AC power from the backup generator 3 to a 220V DC output.

The power system 1 also shows an energy storage device such as a battery, flywheel, or, super capacitor 7, connected to the outputs of both the rectifiers 5 and 6. The energy storage device or battery 7 can be charged from the AC power sources 2 and 3, via the rectifiers 5 and 6, and thereby also supply DC power output, particularly in the event of a failure of one or both of the AC grid supply 2 or the backup generator power source 3.

The power system 1, is shown in FIG. 1, to further include an inverter 8, the input which is connected to the DC outputs of both the rectifiers 5 and 6, and also the energy storage device 7.

The present invention has thereby removed the requirement for a source changeover device, and as such, the reliability/availability of the complete no break power solution for data centres is improved.

FIG. 1 further illustrates how one or more optional backup generators may be interconnected into the power system. Such an optional backup generator 8, having its associated rectifier 9 may, for example, be a renewable energy source generator (eg. solar panels or wind generators).

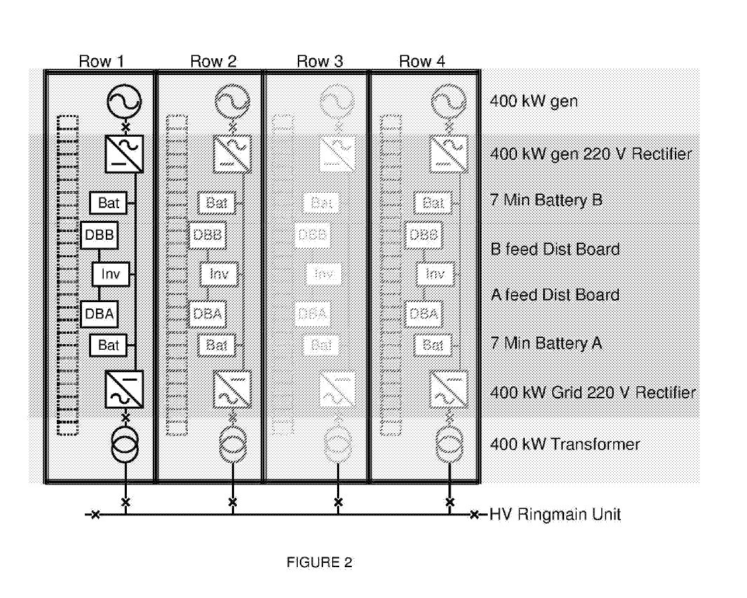

FIG. 2 shows a composite power distribution system, in accordance with the present invention, which uses a plurality of the power systems, as shown in FIG. 1, provided in parallel. The particular embodiment illustrated shows four rows, each row being a power system as illustrated in FIG. 1. An advantage of providing a plurality of power systems in parallel with each other is to ensure the data centre power system is tolerant of faults or failures of one power system thereby increasing the total power system availability.

The invention achieves this by using multiple micro-modular, hot swappable rectifiers to power the no break power system rectifiers, operating at a higher DC voltage of typically 220 volt DC or 380 volt DC. This approach improves the availability of the data centre no break power system.

The invention also adopts a design approach of using multiple micro-modular, hot swappable inverters to power the data centre computer equipment from the DC energy storage. This approach improves the availability of the data centre no break power system.

The invention also installs a second micro-modular hot swappable rectifier into the no break power system, to eliminate the source changeover device typically used in such a system. This second rectifier AC power input is connected to the output of the standby generator. The DC output of this second rectifier is then connected directly to the Grid rectifier DC output in such a way that they are the same polarity and charge the same energy storage device.

Throughout this specification, the term micro modular hot swappable is used to generally refer to very small power modules typically less than 5 kW power. Hot swappable means the power module can be safely disconnected, withdrawn, replaced and reconnected while adjacent micro modules are still connected, powered and operational.

The installation of this second rectifier system attached to the standby generator removes the need for any source changeover device.

Removing the source changeover device removes the risk of mal-operation.

Use of the micro-modular hot swappable rectifier modules results in simplified maintenance, high availability and fewer disruptions to the power system.

The use of dual rectifier systems allows concurrent operation of both the grid and standby generator, which means testing of the generators presents little risk to the data centre operators.

Additionally the invention allows more than one supplementary rectifier to be utilised. This means other standby energy sources such as secondary standby generators or renewable energy sources such as wind and solar to be connected to the same DC bus bar to provide seamless supply of energy to the data centre computer equipment from a wide selection of sources.

The use of micro-modular rectifiers means the energy storage device is electrically galvanically isolated from both the grid and generator supplies. This means the transference of common mode electrical noise between the energy sources and the delicate data centre computer equipment is minimised if not completely removed.

The use of micro-modular inverters provides complete galvanic isolation between the energy storage devices and the computer equipment loads. There is no electrical connection between the input AC power system neutral and the inverter output neutral that is connected to the data centre loads. This additionally isolates the computer equipment from common mode electrical noise in the systems.

The micro-modular hot swappable rectifiers preferably chosen for use in this invention are set to deliver industrial standard DC voltages or either 220 volt DC or 380 volt DC which are isolated from earth. Both these voltages are lower than the 480 volt DC typical in most UPS energy storage battery systems. This makes the new solution electrically safer for technicians and electricians.

Many AC powered devices are able to operate on DC voltages so long as the voltage is similar to the rating of the connected device. As a result the invention is designed to use either 220 volt DC or 380 volt DC to enable the no break energy storage system DC power to be directly connected to a selection of the computer systems available in the market today without the need to install DC to AC inverters. This improves system efficiency and resilience through the reduction of the number of circuit breakers and power conversion stages in the computer system power supply circuit.

This invention differs from other computer room no break power systems in the removal of all source transfer devices, the use of micro-modular and hot swappable components that are galvanically isolated from each other and the use of multiple rectifiers feeding into the one energy storage device to enable a wide selection of possible energy sources.

Commercial advantages of the invention include a 30% lower capital cost, ease of construction and maintenance. Also infrastructure is only provided on an as-needed basis to meet demand, in contrast to current data centre design where the majority of the final infrastructure needs to be provided upfront tying up capital. Furthermore, less plant space is required realising additional space for IT infrastructure. As a result higher reliability of the overall system is achieved, than is normally provided in typical data centre power supply solutions.

The use of a micro-modular hot swappable rectifier on the Grid Power supply results in a number of advantages of the invention over the prior art:
a) No source change over device on the input;
b) Input circuit breaker is always closed. Rectifier starts and delivers power to the energy storage device as soon as the grid power is available without requiring the source transfer device to operate;
c) Module failures do not cause rectifier failure;
d) Any failed rectifier is quickly and easily replaced with no tools;
e) Full galvanic isolation between the input and outputs; and,
f) Lower voltage DC for the energy storage device makes an electrically safer solution.

The use of a micro-modular hot swappable rectifier on the standby generator Power supply also results in a number of advantages, including:
a) No source change over device on the input;
b) Input circuit breaker is always closed. Rectifier starts and delivers power to the energy storage device as soon as the standby generator power is available without requiring the source transfer device to operate;
c) Module failures do not cause rectifier failure;
d) Any failed rectifier is quickly and easily replaced with no tools;
e) Full galvanic isolation between the input and outputs;
f) Lower voltage DC for the energy storage device makes an electrically safer solution; and,
g) Allows full testing of the standby generator at any time with minimal risk.

The use of a micro-modular hot swappable inverter on the energy storage device to provide AC power to the data centre equipment results in the following advantages:
a) Module failures do not cause inverter failure;
b) Any failed inverter is quickly and easily replaced with no tools;
c) Full galvanic isolation between the input and outputs;
d) No direct connection of the power supply neutral between any of the energy source inputs and the AC supply to the servers which means no cross talk noise; and,
e) Allows full testing of the standby generator at any time with minimal risk.

In a preferred embodiment of this invention, a 220 volt DC battery voltage rather than the alternate 380 volt DC battery voltage is used. The reason for this is to utilise a little known power system feature where a majority of modern AC powered devices can operate on DC voltages so long as they are a similar voltage to the AC voltage rating. A 380 volt DC battery is too high for this feature to be enabled. This means that:
a) Normal AC powered computer servers can be powered directly from a 220 volt DC source without needing an intermediary inverter. This removes the cost and energy losses of the inverter from the power system;
b) Power distribution can be paralleled from a number of sources at the load end of the wires using a simple diode blocking arrangement;
c) Using this arrangement of DC power and diode blocking allows multiple sources to be delivered concurrently to each computer server to provide greatly elevated levels of redundancy. Typically a computer server has at most two independent sources of power. This invention allows several (more than 2) sources of power to be delivered to the computer servers;
d) The use of the 220 volt DC power directly to the computer server allows the final conversion of power to be installed local to the server. This allows the power voltage, frequency, capacity and resilience to be installed as needed to suit the computer system criticality and value. Such an arrangement is unique in the data centre technical space.

As will be appreciated from the description provided hereinbefore, the invention therefore requires no source transfer switchboard for the no break power system. This results in various advantages including:
a) less cost as there is less equipment required to deliver power to the computer equipment;
b) less cost for power cables as the primary power cables are shorter and smaller;
c) improved reliability as there are fewer active components in the power supply system that can fail;
d) shorter installation time as there are fewer items of equipment to install; and,
e) greater flexibility for the no break power system to meet potential future data centre loads. The input source change over switch creates a point of maximum capacity in the power supply. The invention through the absence of a source changeover switch does not have such a capacity constraint.

The present invention has been herein described with reference to particular examples. It will be apparent to persons skilled in the art, that numerous variations and modifications will be capable of being made to the specific exemplary embodiments hereinbefore described. All such variations and modifications should be considered to fall within the spirit and scope of the invention.

1. A power system, including:
a first rectifier, having an input adapted to be connected to a first AC (grid) power source, and, a DC output;
a second rectifier, having an input adapted to be connected to a second AC power source, and, a DC output, wherein the DC output of the first rectifier is directly connected to the DC output of the second rectifier;
an electrical or mechanical energy storage device having an input connected to the DC outputs of each of the first and second rectifiers, and, a DC output;
an inverter, having an input which is electrically connected to the DC outputs of both the rectifiers and the energy storage device, and, an AC output which is adapted to be connected to an AC load;
wherein, in use, the load is adapted to concurrently draw power from each inverter and\or the energy storage device.

2. A power system as claimed in claim 1, further including:
at least one additional rectifier, having an input adapted to be connected to an additional AC power source, and, a DC output, wherein, the at least one additional rectifier is directly connected to the DC output of the first and second rectifiers.

3. A power system as claimed in claim 1, wherein each rectifier is connected to an AC power source including a grid power source.

4. A power system as claimed in claim 1, wherein the energy storage device is adapted to directly supply DC power to a DC load, the energy storage device including a battery.

5. A power system as claimed in claim 1, wherein the DC outputs deliver a DC voltage which matches the DC input voltage of the load components.

6. A power system as claimed in claim 1, wherein each rectifier is embodied in a modular form to facilitate quick and easy replacement.

7. A power system as claimed in claim 6, wherein each rectifier is a micro modular hot swappable rectifier.

8. A power system as claimed in claim 1, wherein the inverter is embodied in modular form to facilitate quick and easy replacement.

9. A power system as claimed in claim 8, wherein said inverter is a micro modular hot swappable inverter.

10. A power system as claimed in claim 1, when connected in parallel with one or more additional power system, to form a composite power distribution system with additional redundancy.

11. A modular form micro modular hot swappable rectifier, adapted to be used in the power system as claimed in claim 1.

12. A modular form micro modular hot swappable inverter, adapted to be used in the power system of claim 1.

13. The power system of claim 1 wherein said second AC power source is abackup generator.

14. The power system of claim 4 wherein said energy storage device is a flywheel.

15. The power system of claim 4 wherein said energy storage device is a super capacitor.

16. The power system of claim 3 wherein said AC power source is a grid power source.

17. The power system of claim 3 wherein said AC power source is a renewable energy source.

18. The power system of claim 17 wherein said renewable energy source is solar.

19. The power system of claim 17 wherein said renewable energy source is wind.
